(19) United States
(12) Patent Application Publication
(10) Pub. No.: US 2019/0119809 A1
(43) Pub. Date: Apr. 25, 2019

(54) METHOD FOR DEPOSITING A COATING OF FIRST METAL ON A SECOND METAL COMPONENT AND COMPONENT PRODUCED BY THE METHOD

(71) Applicant: GM GLOBAL TECHNOLOGY OPERATIONS LLC, Detroit, MI (US)

(72) Inventors: Huaxin Li, Rochester Hills, MI (US); Dale A. Gerard, Bloomfield Hills, MI (US); Richard D. Ricchi, Lapeer, MI (US)

(21) Appl. No.: 15/789,052

(22) Filed: Oct. 20, 2017

(51) Int. Cl. C23C 14/58; C23C 24/00; C23C 14/02; C23C 14/28; C23C 14/16; F02F 3/10

(52) U.S. Cl. CPC C23C 14/5813; C23C 24/00; F02F 3/10; C23C 14/28; C23C 14/16; C23C 14/022

(57) ABSTRACT

A method for depositing a coating of a first metal on a second metal component includes applying a first laser beam to a surface of the second metal to remove a portion of an oxide layer from the surface, and applying a second laser beam to deposit a coating of a first metal on the surface immediately following the first laser beam and a component made by the method.

### FIELD

The present disclosure relates to a method for depositing a coating of a first metal on a second metal component and component produced by the method.

### INTRODUCTION

This introduction generally presents the context of the disclosure. Work of the presently named inventors, to the extent it is described in this introduction, as well as aspects of the description that may not otherwise qualify as prior art at the time of filing, are neither expressly nor impliedly admitted as prior art against this disclosure.

Piston pins are used to connect a connecting rod with a piston in an engine. The piston pin fits in a pin bore of the piston, and the connecting rod fits around the piston pin between two portions of the pin bore. The piston pin must be designed to meet bending deflection, ovaling deflection, and stress constraints. An exemplary embodiment of a piston pin 100 which may meet these constraints is illustrated by FIGS. 1 and 2 and is disclosed in co-pending, co-assigned, pending U.S. patent application Ser. No. 14/923,597, the disclosure of which is incorporated herein in its entirety. The piston pin 100 described by that reference includes an aluminum core 102 that is press-fit into a steel cylinder 104.

While the piston pin disclosed by the above, cited reference may satisfy multiple constraints, it is desirable to reduce the mass of the piston pin. Any further reduction in mass will result in substantial improvements in fuel economy, efficiency, and performance.

### SUMMARY

In an exemplary aspect, a method for depositing a coating of a first metal on a second metal component includes applying a first laser beam to a surface of the second metal to remove a portion of an oxide layer from the surface, and applying a second laser beam to deposit a coating of a first metal on the surface immediately following the first laser beam.

In another exemplary aspect, the method further includes applying a third laser beam to a surface of the second metal coating to re-melt at least a portion of the coating, and cooling the re-melted coating such that the hardness and densification of the surface of the coating is increased.

In another exemplary aspect, the method further includes surface finishing a surface of the coating.

In another exemplary aspect, the method further includes providing an inert gas to the surface between the applying of the first laser beam and the applying of the second laser beam.

In another exemplary aspect, the second laser depositing of the coating includes providing a powder of the first metal.

In another exemplary aspect, the second laser depositing of the coating comprises feeding a wire of the first metal.

In another exemplary aspect, the first metal is a steel alloy.

In another exemplary aspect, the second metal is an aluminum alloy.

In this manner, the mass of a component produced by the method may be significantly reduced which, in a reciprocating mass in an engine, such as, for example, a piston pin, may significantly improve fuel economy, efficiency, performance, reliability, and durability.

Further areas of applicability of the present disclosure will become apparent from the detailed description provided below. It should be understood that the detailed description and specific examples are intended for purposes of illustration only and are not intended to limit the scope of the disclosure.

The above features and advantages, and other features and advantages, of the present invention are readily apparent from the detailed description, including the claims, and exemplary embodiments when taken in connection with the accompanying drawings.

### BRIEF DESCRIPTION OF THE DRAWINGS

The present disclosure will become more fully understood from the detailed description and the accompanying drawings, wherein:

FIG. 1 is a perspective view of a piston pin 100;

FIG. 2 is a axial end view of the piston pin 100; and

FIG. 3 is a schematic illustration of an exemplary laser metal deposition system 300 in accordance with the present disclosure.

In the drawings, reference numbers may be reused to identify similar and/or identical elements.

### DETAILED DESCRIPTION

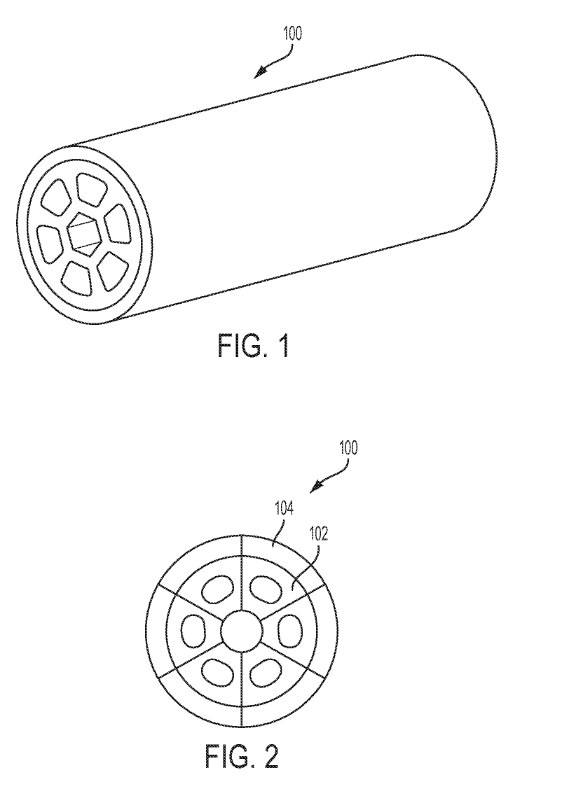

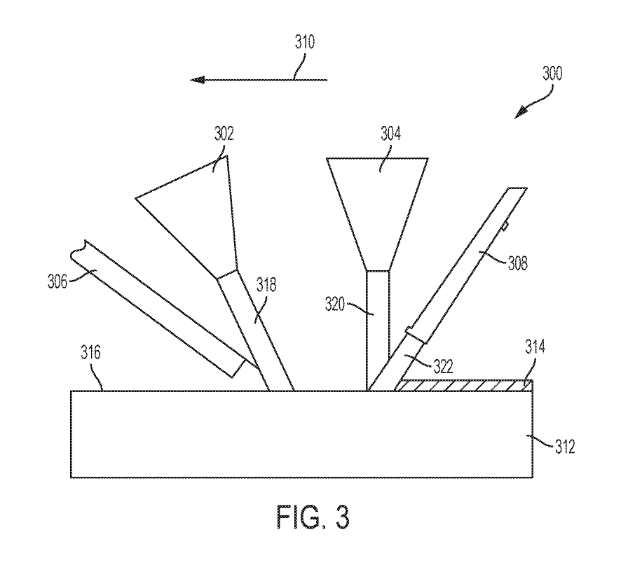

Referring now to FIG. 3, a schematic illustration of an exemplary laser metal deposition system 300 in accordance with the present disclosure is illustrated. The laser metal deposition system 300 includes a first laser source 302, a second laser source 304, a suction source 306 and a metal supply 308. The first laser source 302, second laser source 304, suction source 306, and metal supply 308 traverse to the left in FIG. 3 relative to a surface 316 of an aluminum component 312. The aluminum component 312 may be a core for a piston pin similar to the aluminum core 102 illustrated by FIGS. 1 and 2. The laser metal deposition system 300 operates to provide a metal coating 314 on the surface 316 of the aluminum core 312 which is firmly bonded directly to the surface 316 of the aluminum core 312. Preferably, the bond between the metal coating 314 and the surface 316 of the aluminum core 312 is a metallurgical bond. In an exemplary embodiment, the metal coating 314 may be a steel coating.

The inventors understood that one of the challenges in obtaining a metallurgical bond to a coating on an aluminum surface is the ability to provide a clean aluminum surface on which to form the bond to a coating. The tendency of aluminum to quickly oxidize makes it very difficult to provide a clean surface. The laser metal deposition system 300 in accordance with the present disclosure addresses this problem by providing a dual laser treatment system which uses a first laser source 302 to remove at least a portion of any oxidation on the surface 316 of the aluminum component 312 and then immediately follows that cleaning with a second laser source 304 which deposits a metal coating 314 on the cleaned surface 316. In this manner, the amount of oxidation is reduced and/or prevented which results in a strong bond between the metal coating 314 and the aluminum component 312. In turn, this enables a significant reduction in mass of a component while continuing to provide the characteristics necessary for the component, such as, for example, a piston pin.

As the laser deposition system 300 moves in the direction of arrow 310 relative to the aluminum component 312, the first laser source 302 provides a first laser beam 318 which removes at least a portion of an oxidation layer (not shown) on the surface 316 of the aluminum component 312. The suction source 306 acts to remove material which may be generated in the vicinity of the first laser beam 318 operating on the surface 316 of the aluminum component 312. For example, the first laser source 302 may vaporize a portion of an oxidized layer and the suction source 306 may then remove the vapors and any particulates generated by the process from the area adjacent to the surface 316. Immediately following the first laser source 302, a second laser source 304 provides a second laser beam 320 which operates together with the metal supply 308 to deposit a coating of metal 314 onto the surface 316 of the aluminum component 312. The second laser beam 320 operates to transform a supply of metal 322 from the metal supply 308 into a metal coating 314 which is firmly bonded to the surface 316. The metal supply 308 may provide the supply of metal in any manner, such as, for example, a supply of metal powder, a metal wire feed, and/or the like without limitation In this manner, the potential for the formation of an aluminum oxide (not shown) on the surface 316 which has been cleaned by the first laser beam 318 before the second laser beam 320 operates to coat the surface 316 with metal is reduced and/or eliminated which results in a strong bond between the metal coating 314 and the surface 316.

Further, in comparison to conventional piston pins which may have been produced by press fitting an aluminum core into a steel cylinder, the present disclosure enables a significant reduction in mass by minimizing the amount of steel in the piston pin to only as much as is necessary to provide the necessary characteristics for a piston pin. For example, the thickness of the steel cylinder in a conventional piston pin may be between about four to six millimeters. In stark contrast, an exemplary embodiment of the present disclosure may provide a steel coating with is only between about 0.7 to 1.0 millimeters. This is a significant reduction in mass while still providing the hardness and strength characteristics necessary for a component such as, for example, for a piston pin. Again, such a reduction in mass may provide a significant improvement in efficiency, performance, reliability and durability, especially when the component is a reciprocating component such as, for example, a piston pin.

Optionally, and preferably, the coating 314 on the surface of the aluminum component 312 may receive further treatment. For example, in a preferred embodiment, a steel coating 314 may be treated in a re-melting process such as, for example, with a third laser source (not shown). In this manner, re-melting of the steel coating 314 on an aluminum core 312 of a piston pin using a third laser may improve the hardness and/or strength of the steel coating 314. This may improve the strength of the piston pin in bending, ovalizing resistance, hoop strength, global strength, improve hardness, and/or reduce brittleness of the coating. Further, and additionally, the coating 314 may be treated by a subsequent surface finishing process.

While the present disclosure generally describes the use of the inventive laser metal deposition system and method for applying a steel coating on an aluminum surface, it is to be understood that the inventive method and system is further applicable to any metal surface and/or coating without limitation. For example, in addition to aluminum, other metals, such as, titanium may also experience oxidation which may otherwise adversely affect any bonding of another metal onto its surface. Similarly, the metal which may be used to form the metal coating is also not limited.

Further, in another exemplary embodiment, the laser metal deposition system 300 may operate within an inert gas atmosphere. An inert gas may reduce and/or prevent any oxidation of the surface which was cleaned by the first laser source 302 before the second laser source 304 applies the metal coating 314. In an exemplary embodiment, an inert gas supply (not shown) may be provided to the laser metal deposition system which encompasses the surface 316 in an inert gas atmosphere.

Additionally, while the components of the laser metal deposition system 300 are illustrated as independent and separate components, any combination of these components, without limitation, may be incorporated into a tool head (not shown). In an exemplary embodiment, the laser metal deposition system 300 may form a tool head which includes the suction source 306, the first laser source 302, the second laser source 304, and the metal supply 308.

The laser metal deposition system 300 in accordance with the present disclosure further provides additional advantages. For example, the first laser source 302 not only operates to remove a portion of an oxidation layer, but also operates to pre-heat the underlying aluminum component 312 which improves the effectiveness of the immediately subsequent second laser source 304 to provide a strong bond between the surface 316 and the metal coating 314.

Another significant advantage and performance characteristic may be provided by the present disclosure. The steel in an automotive component such as, for example, a piston pin may include tempered martensite and does not have a lot of untransformed austenite. Untransformed austenite is undesirable because if/when that austenite does transform, it may expand which may result in a piston pin growing and seizing in the piston and/or connecting rod. To avoid untransformed austenite in piston pins which are conventionally produced, careful heat treatment may be required. Further, a heating and cooling test may be required to ensure that austenite is not transforming in the piston pin.

In contrast to these conventional components, a component produced in accordance with an exemplary embodiment of the present disclosure may completely avoid an untransformed austenite problem. The significant reduction in mass of the steel may result in a significant reduction in growth of the pin even in the presence of transforming austenite which may then completely avoid and or reduced the likelihood of seizure of the piston pin within the piston and/or connecting rod.

While the present disclosure has described a method and system for producing a coating on a metal component for use as a piston pin, it is to be understood that the present method and system may be applied to any component, in particular, those components subject to reciprocating motion in an engine may also benefit from the present disclosure such as, for example, a connecting rod pin and the like without limitation.

This description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A method for depositing a coating of a first metal on a second metal component, the method comprising:
applying a first laser beam to a surface of the second metal to remove a portion of an oxide layer from the surface; and
applying a second laser beam to deposit a coating of a first metal on the surface immediately following the first laser beam.

2. The method of claim 1, further comprising:
applying a third laser beam to a surface of the second metal coating to re-melt at least a portion of the coating; and
cooling the re-melted coating such that the hardness and densification of the surface of the coating is increased.

3. The method of claim 1, further comprising surface finishing a surface of the coating.

4. The method of claim 1, further comprising providing an inert gas to the surface between the applying of the first laser beam and the applying of the second laser beam.

5. The method of claim 1, wherein the second laser depositing of the coating comprises providing a powder of the first metal.

6. The method of claim 1, wherein the second laser depositing of the coating comprises feeding a wire of the first metal.

7. The method of claim 1, wherein the first laser beam further preheats the surface in preparation for the second laser depositing of the coating.

8. The method of claim 1, wherein the first metal comprises a steel alloy.

9. The method of claim 1, wherein the second metal comprises an aluminum alloy.

10. A component for an engine in a vehicle propulsion system having a coating of a first metal on a core of a second metal, the component produced by a process comprising the steps of:
providing a core comprising the second metal;
applying a first laser beam to a surface of the core to remove a portion of an oxide layer from the surface; and
applying a second laser beam to deposit the coating of the first metal on the surface immediately following the first laser beam.

11. The component of claim 10, wherein the component is produced by a process further comprising the steps of:
applying a third laser beam to a surface of the coating to re-melt at least a portion of the coating; and
cooling the re-melted coating such that the hardness and densification of the surface of the coating is increased.

12. The component of claim 10, wherein the component comprises a piston pin.

13. The component of claim 10, wherein the component comprises a connecting rod pin.

14. The component of claim 10, wherein the first alloy comprises a steel alloy.

15. The component of claim 10, wherein the second alloy comprises an aluminum alloy.

16. The component of claim 10, wherein the component is produced by a process further comprising the steps of providing an inert gas to the surface between the applying of the first laser beam and the applying of the second laser beam.

17. The component of claim 10, wherein the second laser depositing of the coating comprises providing a powder of the first metal.

18. The component of claim 10, wherein the second laser depositing of the coating comprises feeding a wire of the first metal.
